(19) United States
(12) Patent Application Publication
(10) Pub. No.: US 2015/0000729 A1
(43) Pub. Date: Jan. 1, 2015

(54) SOLAR CELL WITH PASSIVATION LAYER AND MANUFACTURING METHOD THEREOF

(71) Applicant: MH SOLAR COMPANY LIMITED, KAOHSIUNG CITY (TW)

(72) Inventors: MEI-HUAN YANG, KAOHSIUNG CITY (TW); CHIUN-YEN TUNG, KAOHSIUNG CITY (TW); CHIN-WEI HSU, KAOHSIUNG CITY (TW); CHENG-LIANG WU, KAOHSIUNG CITY (TW); KUN-SAIN CHEN, KAOHSIUNG CITY (TW); WEI-SHENG CHAO, KAOHSIUNG CITY (TW); YING-JIE PENG, KAOHSIUNG CITY (TW); TE-CHIH HUANG, KAOHSIUNG CITY (TW); MING-ZEN CHUANG, KAOHSIUNG CITY (TW)

(73) Assignee: MH SOLAR COMPANY LIMITED, KAOHSIUNG CITY (TW)

(21) Appl. No.: 14/186,457

(22) Filed: Feb. 21, 2014

(30) Foreign Application Priority Data
Jun. 28, 2013 (TW) 102123167
Jun. 28, 2013 (TW) 102123171

(51) Int. Cl. H01L 31/0687; H01L 31/0216

(52) U.S. Cl. CPC H01L 31/0687; H01L 31/02168
USPC 136/255; 438/72

(57) ABSTRACT

A solar cell includes a vertical multi-junction (VMJ) cell and a passivation layer. The VMJ cell includes a plurality of PN junction substrates spaced from each other and a plurality of electrode layers. Each of the PN junction substrates includes a P+ type end surface, a P type end surface, an N type end surface, and an N+ type end surface. Each of the electrode layers is disposed between and connected to two adjacent PN junction substrates and has an exposing surface. The passivation layer covers the P+ type end surfaces, the P type end surfaces, the N type end surfaces, the N+ type end surfaces and the exposing surfaces to reduce a carrier recombination probability induced by absorbing sunlight. A method of manufacturing the solar cell includes providing a vertical multi-junction (VMJ) cell and forming a passivation layer on the VMJ cell.

### FIELD

The disclosure relates to a solar cell and manufacturing method thereof, more particular to a solar cell with a passivation layer.

### BACKGROUND

Vertical multi-junction (VMJ) cell is a solar cell device which may allow output voltage higher than conventional single junction cells. Particularly the VMJ cell may operate in a high concentrated light environment. However, a carrier recombination probability is challenging to modern VMJ cells because the carrier recombination easily occurs in a surface of the VMJ cell, thereby reducing the photovoltaic conversion efficiency. The photovoltaic conversion efficiency decay causes the VMJ cell to be less widely used.

In view of the foregoing, it is greatly desired to develop a solar cell or method which may reduce the carrier recombination probability.

### DOCUMENT IN THE PRIOR ART

### Patent Document

Patent document 1: US Patent Publication No. U.S. Pat. No. 4,332,973

Patent document 2: US Patent Publication No. U.S. Pat. No. 4,409,422

Patent document 3: US Patent Publication No. U.S. Pat. No. 4,516,314

Patent document 4: US Patent Publication No. U.S. Pat. No. 6,333,457

Patent document 5: CN Patent Application No. 102668102 A

Patent document 6: TW Patent Application No. 096123802

Patent document 7: TW Patent Application No. 095135676

Patent document 8: EP Patent Publication No. EP2077584 A2

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1a illustrates a side view of a solar cell in accordance with some embodiments of the present disclosure.

FIG. 1b illustrates a partial enlarged view of a solar cell in accordance with some embodiments of the present disclosure.

FIG. 2 illustrates a perspective view of a vertical multi-junction cell in accordance with some embodiments of the present disclosure.

FIG. 3 illustrates a side view of a solar cell in accordance with some embodiments of the present disclosure.

FIG. 4 illustrates a side view of a solar cell in accordance with some embodiments of the present disclosure.

FIG. 5 illustrates a side view of a solar cell in accordance with some embodiments of the present disclosure.

FIG. 6 is a flow diagram of a method of manufacturing a solar cell in accordance with some embodiments of the present disclosure.

FIGS. 7a to 7b illustrate schematic views of a solar cell in various processes corresponding to the method of FIG. 6.

FIG. 8 is a flow diagram of a method of manufacturing a solar cell in accordance with some embodiments of the present disclosure.

FIG. 9 illustrates a schematic view of forming an anti-reflective layer on a solar cell in accordance with some embodiments of the present disclosure.

### DETAILED DESCRIPTION OF THE INVENTION

It is to be understood that the following disclosure provides many different embodiments or examples, for implementing different features of various embodiments. Specific examples of components and arrangements are described below to simplify the present disclosure. The present disclosure may, however, be embodied in many different forms and should not be construed as being limited to the embodiments set forth herein; rather, these embodiments are provided so that this description will be thorough and complete, and will fully convey the present disclosure to those of ordinary skill in the art. It will be apparent, however, that one or more embodiments may be practiced without these specific details.

In addition, the present disclosure may repeat reference numerals and/or letters in the various examples. This repetition is for the purpose of simplicity and clarity and does not in itself dictate a relationship between the various embodiments and/or configurations discussed.

It will be understood that when an element is referred to as being “on” another element, it can be directly on the other element or intervening elements may be present. In contrast, when an element is referred to as being “directly on” another element, there are no intervening elements present.

It will be understood that singular forms “a”, “an” and “the” are intended to include the plural forms as well, unless the context clearly indicates otherwise.

Unless otherwise defined, all terms (including technical and scientific terms) used herein have the same meaning as commonly understood by one of ordinary skill in the art to which this invention belongs. It will be further understood that terms; such as those defined in commonly used dictionaries, should be interpreted as having a meaning that is consistent with their meaning in the context of the relevant art and the present disclosure, and will not be interpreted in an idealized or overly formal sense unless expressly so defined herein.

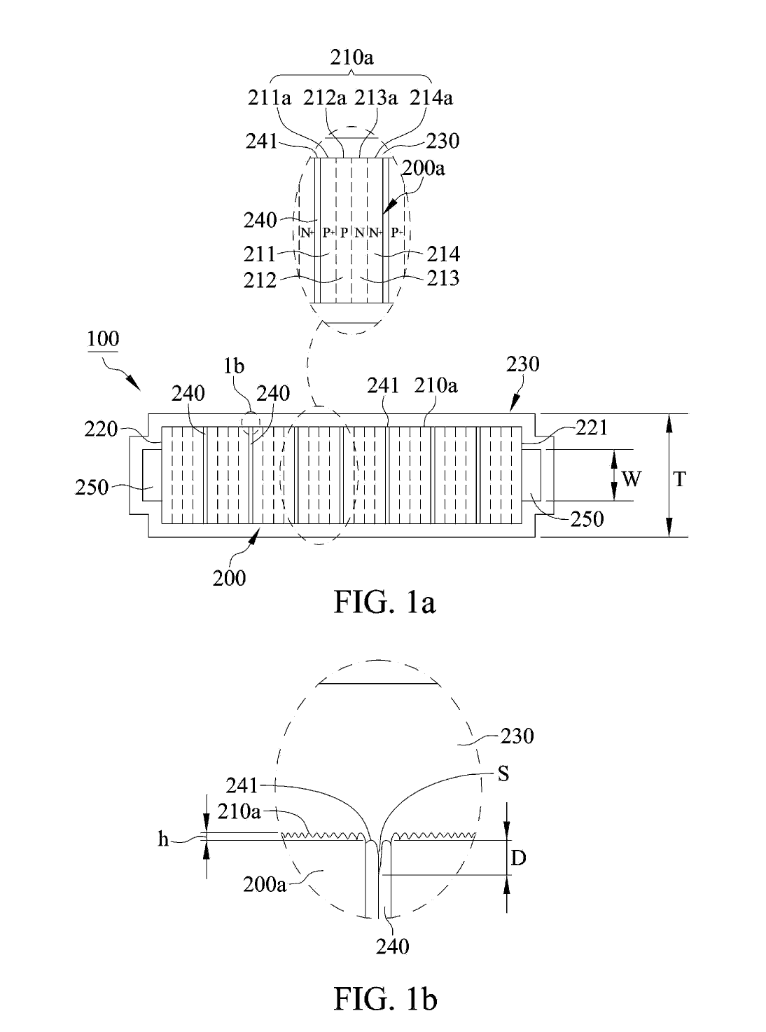

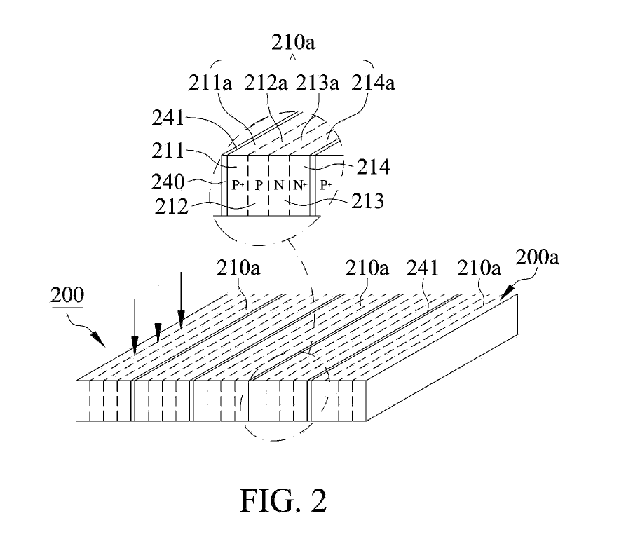

FIG. 1a illustrates a side view of a solar cell in accordance with some embodiments of the present disclosure. FIG. lb illustrates a partial enlarged view of a solar cell in accordance with some embodiments of the present disclosure. FIG. 2 illustrates a perspective view of a vertical multi-junction cell in accordance with some embodiments of the present disclosure.

Referring to FIGS. 1a, 1b, and 2, a solar cell 100 is designed to reduce a carrier recombination probability induced by absorbing sunlight. The solar cell 100 includes a vertical multi-junction (VMJ) cell 200 and a passivation layer 230 disposed on the VMJ cell 200.

The vertical multi-junction (VMJ) cell 200 includes a plurality of PN junction substrates 200a and a plurality of electrode layers 240. The PN junction substrates 200a are spaced from each other. The PN junction substrates 200a are made of silicon (Si), and the silicon purity is between about 4N and about 11N. In some embodiments, the PN junction substrates 200a may be made of one selected from the group consisting of GaAs, Ge, InGaP, and their compositions. Each of the electrode layers 240 is disposed between and connected to two adjacent PN junction substrates 200a, which can provide ohmic contacts with low resistance, high strength bonding, and well thermal conduction. In some embodiments, the electrode layers 240 are made of one selected from the group consisting of Si, Ti, Co, W, Hf, Ta, Mo, Cr, Ag, Cu, Al, and their alloy mixtures.

In order to improve carrier injections and ohmic contacts of the VMJ cell 200, each of the PN junction substrates 200a includes a light receiving surface 210a, a P+ type diffuse doping layer 211, a P type diffuse doping layer 212, an N type diffuse doping layer 213 and an N+ type diffuse doping layer 214. The P type diffuse doping layer 212 is connected to the P+ type diffuse doping layer 211; the N type diffuse doping layer 213 is connected to the P type diffuse doping layer 212; and the N+ type diffuse doping layer 214 is connected to the N type diffuse doping layer 213. The P+ type diffuse doping layer 211 and the N+ type diffuse doping layer 214 of one PN junction substrate 200a are connected to different electrode layers 240.

The P+ type diffuse doping layer 211 has a P+ type end surface 211a. In some embodiments, a doping concentration of the P+ type diffuse doping layer 211 is between about 10¹⁹ atom/cm³ and about 10²¹ atom/cm³. In some embodiments, a thickness of the P+ type diffuse doping layer 211 is between about 0.3 μm and about 3 μm.

The P type diffuse doping layer 212 has a P type end surface 212a. In some embodiments, a doping concentration of the P type diffuse doping layer 212 is between about 10¹⁶ atom/cm³ and about 10²⁰ atom/cm³. In some embodiments, a thickness of the P type diffuse doping layer 212 is between about 1 μm and about 50 μm.

The N type diffuse doping layer 213 has an N type end surface 213a. In some embodiments, a doping concentration of the N type diffuse doping layer 213 is between about 10¹⁶ atom/cm³ and about 10²⁰ atom/cm³. In some embodiments, a thickness of the N type diffuse doping layer 213 is between about 1 μm and about 50 μm.

The N+ type diffuse doping layer 214 has an N+ type end surface 214a. In some embodiments, a doping concentration of the N+ type diffuse doping layer 214 is between about 10¹⁹ atom/cm³ and about 10²¹ atom/cm³. In some embodiments, a thickness of the N+ type diffuse doping layer 214 is between about 0.3 μm and about 3 μm.

In some embodiments, the light receiving surface 210a includes the P+ type end surface 211a of the P+ type diffuse doping layer 211, the P type end surface 212a of the P type diffuse doping layer 212, the N type end surface 213a of the N type diffuse doping layer 213 and the N+ type end surface 214a of the N+ type diffuse doping layer 214. In some embodiments, the light receiving surface 210a is an uneven surface.

Each of the electrode layers 240 has an exposing surface 241. To prevent the electrode layers 240 from being damaged in the process, there is a height difference h between the exposing surface 241 of each of the electrode layers 240 and the light receiving surface 210a of each of the PN junction substrates 200a. In some embodiments, a position of the exposing surface 241 is lower than that of the light receiving surface 210a.

In order to reduce the carrier recombination probability, the passivation layer 230 is provided to cover the P+ type end surfaces 211a of the P+ type diffuse doping layers 211, the P type end surfaces 212a of the P type diffuse doping layers 212, the N type end surfaces 213a of the N type diffuse doping layers 213, the N+ type end surfaces 214a of the N+ type diffuse doping layers 214 and the exposing surfaces 241 of the electrode layers 240. The passivation layer 230 is formed by an atomic layer deposition (ALD) process. Furthermore, the passivation layer 230 is penetrable to light and is made of one selected from the group consisting of Al₂O₃, HfO₂, La₂O₃, SiO₂, TiO₂, ZnO, ZrO₂, Ta₂O₅, In₂O₃, SnO₂, ITO, Fe₂O₃, Nb₂O₅, MgO, Er₂O₃, WN, Hf₃N₄, Zr₃N₄, AlN, and TiN.

In addition to reduce the carrier recombination probability, the passivation layer 230 also can be used to mend surface defects and dangling bonds of the PN junction substrates 200a, thereby reducing light induced degradation and enhancing the photovoltaic conversion efficiency. In some embodiments, a thickness of the passivation layer 230 is between about 10 nm and about 180 nm.

To improve a bonding strength between the passivation layer 230 and the electrode layers 240, each of the electrode layers 240 also includes a groove S recessed from the exposing surface 241, and the grooves S of the electrode layers 240 are filled with the passivation layer 230. In some embodiments, a depth D of the groove S is greater than the height difference h.

The VMJ cell 200 also includes a first end surface 220, a second end surface 221 and at least two conducting electrodes 250. The second end surface 221 is opposite to the first end surface 220. The conducting electrodes 250 are separately disposed on the first and second end surfaces 220, 221. The conducting electrodes 250 are used to output electric energy generated from the VMJ cell 200. In some embodiments, the conducting electrodes 250, the first end surface 220 and the second end surface 221 are covered with the passivation layer 230 to reduce the carrier recombination probability. In some embodiments, a width W of each of the conducting electrodes 250 is smaller than a thickness T of the VMJ cell 200.

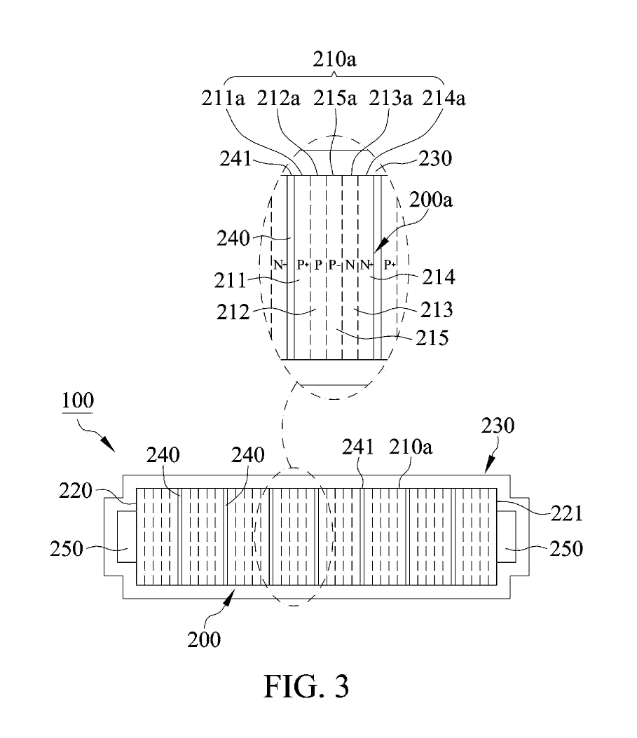

FIG. 3 illustrates a side view of a solar cell in accordance with some embodiments of the present disclosure.

Referring to FIG. 3, each of the PN junction substrates 200a can further include a P− type diffuse doping layer 215. The P− type diffuse doping layer 215 is disposed between and connected to the P type diffuse doping layer 212 and the N type diffuse doping layer 213. The P− type diffuse doping layer 215 has a P− type end surface 215a, and the P− type end surface 215a is also covered with the passivation layer 230 to reduce the carrier recombination probability. In some embodiments, a doping concentration of the P− type diffuse doping layer 215 is between about 10¹⁴ atom/cm³ and about 10¹⁸ atom/cm³.

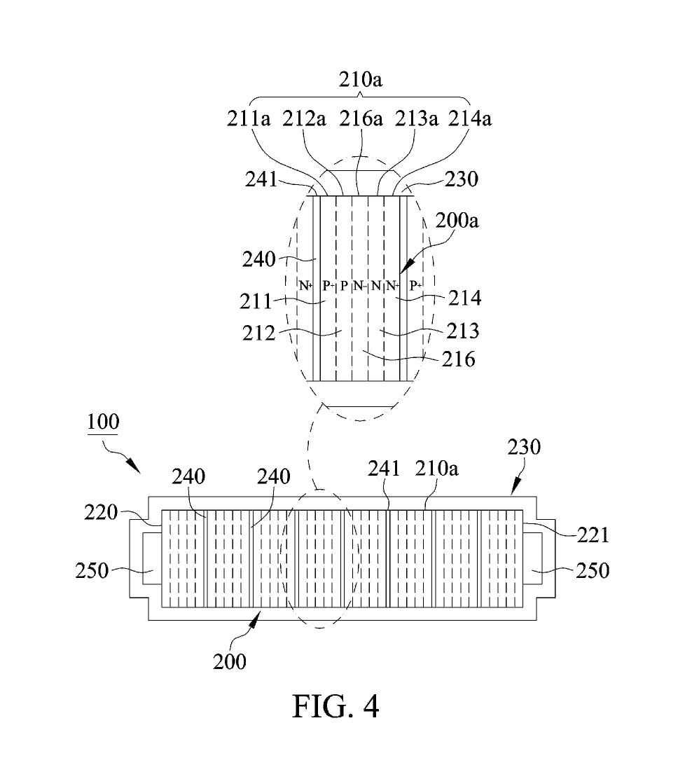

FIG. 4 illustrates a side view of a solar cell in accordance with some embodiments of the present disclosure.

Referring to FIG. 4, each of the PN junction substrates 200a can further include an N− type diffuse doping layer 216. The N− type diffuse doping layer 216 is disposed between and connected to the P type diffuse doping layer 212 and the N type diffuse doping layer 213. The N− type diffuse doping layer 216 has an N− type end surface 216a, and the N− type end surface 216a is also covered with the passivation layer 230 to reduce the carrier recombination probability. In some embodiments, a doping concentration of the N− type diffuse doping layer 216 is between about 10¹⁴ atom/cm³ and about 10¹⁸ atom/cm³.

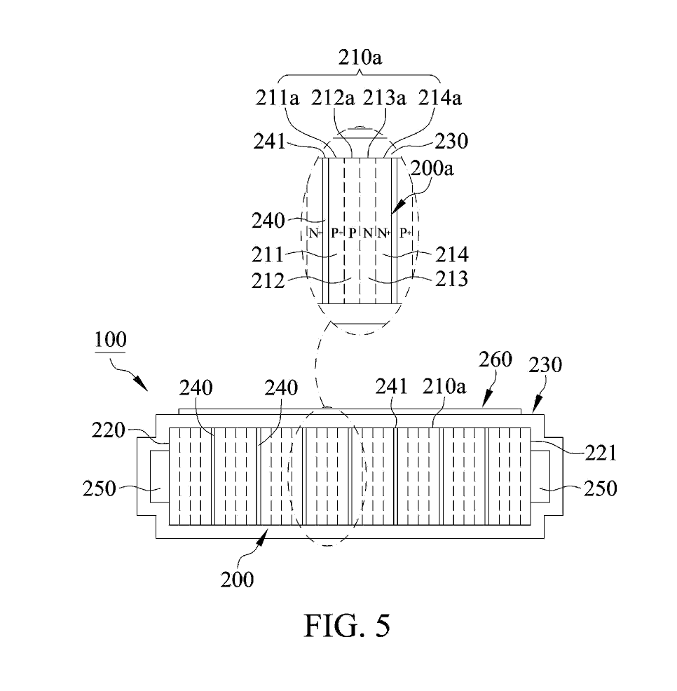

FIG. 5 illustrates a side view of a solar cell in accordance with some embodiments of the present disclosure.

Referring to FIG. 5, the solar cell 100 can further include an anti-reflective layer 260. The anti-reflective layer 260 covers part of the passivation layer 230 to reduce surface reflections, and the anti-reflective layer 260 is penetrable to light. In some embodiments, the anti-reflective layer 260 is formed by a plasma enhanced chemical vapor deposition (PECVD) process. In some embodiments, the anti-reflective layer 260 is made of dielectric material selected from the group consisting of Si₃N₄ and SiO₂. In some embodiments, a thickness of the anti-reflective layer 260 is between about 10 nm and about 80 nm.

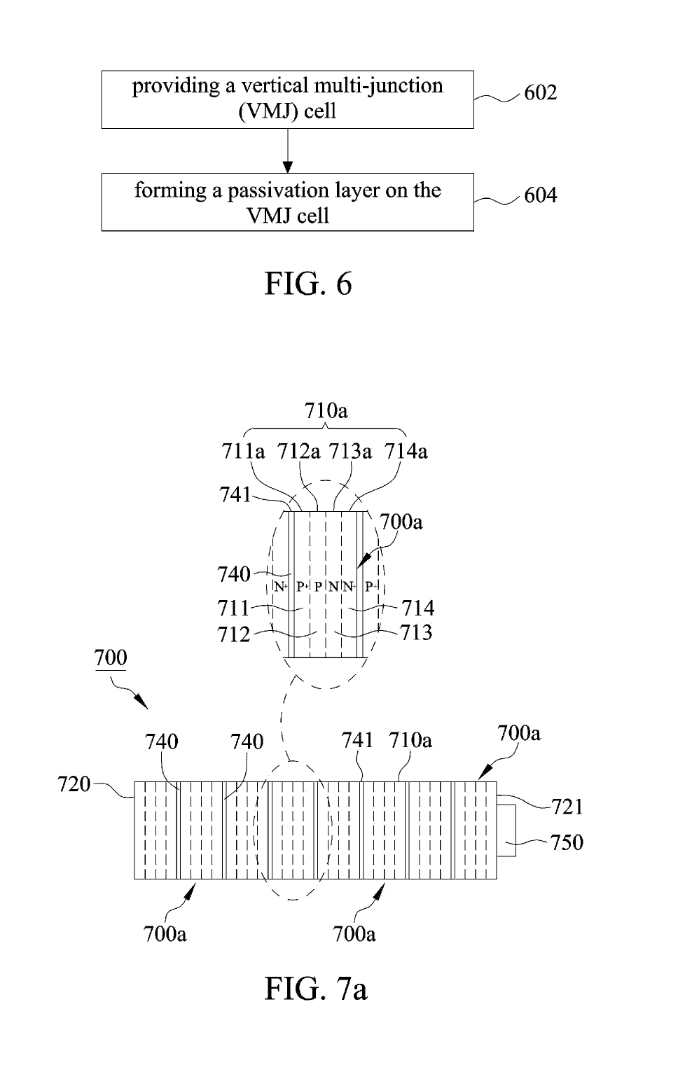

FIG. 6 is a flow diagram of a method of manufacturing a solar cell in accordance with some embodiments of the present disclosure.

Referring to FIG. 6, a method 600 includes operation 602 in which a vertical multi-junction (VMJ) cell is provided. The method 600 continues with operation 604 in which a passivation layer is formed on the VMJ cell. The various operations of FIG. 6 are discussed below in more detail in association with schematic views corresponding to the operations of the flow diagram.

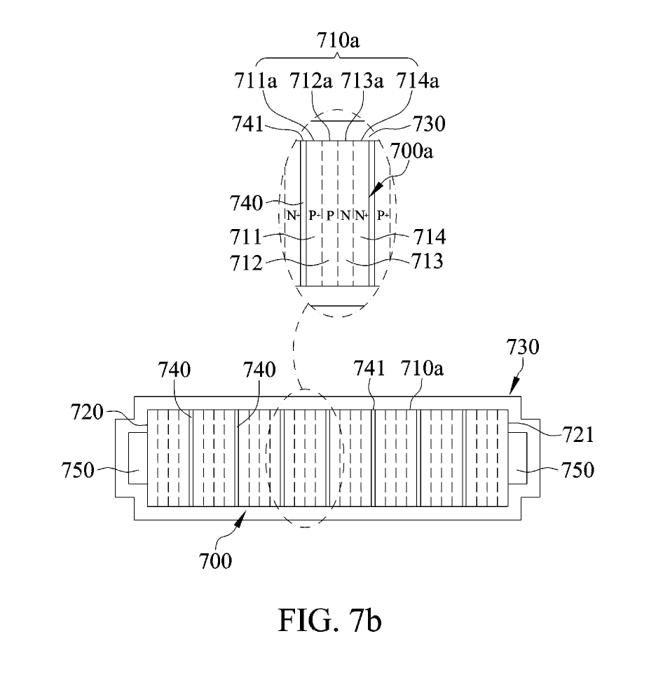

FIGS. 7a to 7b illustrate schematic views of a solar cell in various processes corresponding to the method of FIG. 6.

In FIG. 7a, a vertical multi-junction (VMJ) cell 700 is provided. The VMJ cell 700 includes a plurality of PN junction substrates 700a and a plurality of electrode layers 740. The PN junction substrates 700a are spaced from each other. The PN junction substrates 200a are made of silicon (Si), and the silicon purity is between about 4N and about 11N. In some embodiments, the PN junction substrates 200a may be made of one selected from the group consisting of GaAs, Ge, InGaP, and their compositions or to any material or compound where the absorption of light generates either electron-hole pairs or causes excitons to occur. Each of the PN junction substrates 700a includes a light receiving surface 710a, a P+ type diffuse doping layer 711, a P type diffuse doping layer 712, an N type diffuse doping layer 713 and an N+ type diffuse doping layer 714. The P+ type diffuse doping layer 711 has a P+ type end surface 711a; the P type diffuse doping layer 712 is connected to the P+ type diffuse doping layer 711 and has a P type end surface 712a; the N type diffuse doping layer 713 is connected to the P type diffuse doping layer 712 and has an N type end surface 713a; and the N+ type diffuse doping layer 714 is connected to the N type diffuse doping layer 713 and has an N+ type end surface 714a. In some embodiments, the light receiving surface 710a includes the P+ type end surface 711a, the P type end surface 712a, the N type end surface 713a and the N+ type end surface 714a. Furthermore, the VMJ cell 700 also includes a first end surface 720, a second end surface 721 opposite to the first end surface and at least two conducting electrodes 750 separately disposed on the first and second end surfaces 720, 721.

Each of the electrode layers 740 is disposed between and connected to two adjacent PN junction substrates 700a, and each of the electrode layers 740 has an exposing surface 741 and a groove S recessed from the exposing surface 741. In some embodiments, the PN junction substrates 700a and the electrode layers 740 are bonded together via thermal processing, and the thermal processing temperature is between about 400° C. and about 800° C. to ensure the electrode layers 740 to have eutectic composition. The eutectic electrode layers 740 can improve the bonding strength between the PN junction substrates 700a.

Referring to FIG. 7b, a passivation layer 730 is formed on the VMJ cell 700 to cover the P+ type end surfaces 711a of the P+ type diffuse doping layers 711, the P type end surfaces 712a of the P type diffuse doping layers 712, the N type end surfaces 713a of the N type diffuse doping layers 713, the N+ type end surfaces 714a of the N+ type diffuse doping layers 714 and the exposing surfaces 741 of the electrode layers 740, thereby reducing the carrier recombination probability and enhancing the extension of the built-in electric field. In some embodiments, the passivation layer 730 may be formed on both sides of the VMJ cell 700, and the light receiving surface 710a can be either side of the VMJ cell 700. In some embodiments, the passivation layer 730 is formed by an atomic layer deposition (ALD) process, and the passivation layer 730 is penetrable to light. In some embodiments, the passivation layer 730 is formed by a plasma atomic layer deposition (PALD) process, and the passivation layer 730 is made of one selected from the group consisting of Al₂O₃, HfO₂, La₂O₃, SiO₂, TiO₂, ZnO, ZrO₂, Ta₂O₅, In₂O₃, SnO₂, ITO, Fe₂O₃, Nb₂O₅, MgO, Er₂O₃, WN, Hf₃N₄, Zr₃N₄, AlN, and TiN.

It is important to control the atomic layer deposition rate because an unsuitable atomic layer deposition rate will make the passivation layer 730 to have non-uniform thickness and surface defects. Therefore, a suitable atomic layer deposition rate is greater than or equal to 0.03 nm/s, and the best atomic layer deposition rate is 0.1 nm/s. Furthermore, the best atomic layer deposition temperature is between about 100° C. and about 350° C.

In some embodiments, the conducting electrodes 750, the first end surface 720 and the second end surface 721 are covered with the passivation layer 730 to reduce the carrier recombination probability. In some embodiments, the grooves S of the electrode layers 740 are filled with the passivation layer 730 to improve a bonding strength between the passivation layer 730 and the electrode layers 740.

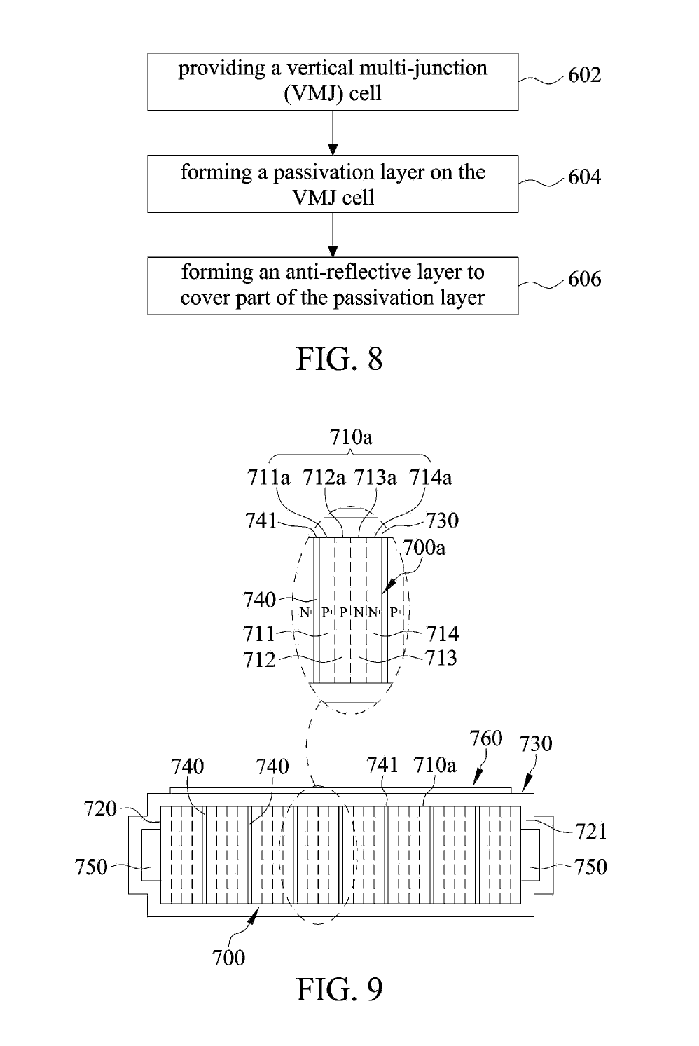

FIG. 8 is a flow diagram of a method of manufacturing a solar cell in accordance with some embodiments of the present disclosure. FIG. 9 illustrates a schematic view of forming an anti-reflective layer on a solar cell in accordance with some embodiments of the present disclosure.

Referring to FIGS. 8 and 9, in some embodiments, the method 600 can further include operation 606 in which an anti-reflective layer 760 is formed to cover part of the passivation layer 730 to reduce surface reflections. In some embodiments, the anti-reflective layer 760 is formed by a plasma enhanced chemical vapor deposition (PECVD) process. In some embodiments, the anti-reflective layer 760 is penetrable to light, and the anti-reflective layer 760 is made of dielectric material selected from the group consisting of Si₃N₄ and SiO₂. In some embodiments, a thickness of the anti-reflective layer 760 is between about 10 nm and about 80 nm.

Table 1 presents the photovoltaic performance for solar cell with and without the passivation layer 730. Under 300 suns (1 sun=0.09 W/cm²) illumination, the solar cell without the passivation layer 730 has an open-circuit voltage (V_{oc}) of 30.03 V, a short-circuit current (I_{sc}) of 0.11 A, a fill factor (F.F) of 0.670, and a photovoltaic conversion efficiency (η) of 6.55%. Interestingly, forming the passivation layer 730 to cover the P+ type end surfaces 711a, the P type end surfaces 712a, the N type end surfaces 713a, the N+ type end surfaces 714a and the exposing surfaces 741 improved the I_{sc} and η values of solar cell to 0.311 A and 22.67%, respectively.

TABLE 1

| Solar cell | I_{sc} (A) | V_{oc} (V) | F.F | η (%) |
|---|---|---|---|---|
| Without passivation | 0.11 | 30.03 | 0.670 | 6.55 |
| With passivation | 0.311 | 32.0 | 0.744 | 22.67 |

Table 2 presents the photovoltaic performance of solar cells based on passivation layers formed by different deposition processes. Under 300 suns illumination, the solar cell based on the passivation layer formed by a thin film deposition process has an open-circuit voltage (V_{oc}) of 32.18 V, a short-circuit current (I_{sc}) of 0.262 A, a fill factor (F.F) of 0.728, and a photovoltaic conversion efficiency (η) of 18.73%. For the passivation layer formed by the plasma atomic layer deposition (PALD) process, I_{sc} and η were improved to 0.311 A and 22.67%, respectively, which values are greater than those obtained by the thin film deposition process.

TABLE 2

| Deposition process | I_{sc} (A) | V_{oc} (V) | F.F | η (%) |
|---|---|---|---|---|
| Plasma atomic layer | 0.311 | 32.0 | 0.744 | 22.67 |
| Thin film | 0.262 | 32.18 | 0.728 | 18.73 |

Moreover, the scope of the present application is not intended to be limited to the particular embodiments of the process, machine, manufacture, and composition of matter, means, methods and steps described in the specification. As those skilled in the art will readily appreciate form the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure.

Accordingly, the appended claims are intended to include within their scope such processes, machines, manufacture, and compositions of matter, means, methods or steps. In addition, each claim constitutes a separate embodiment, and the combination of various claims and embodiments are within the scope of the invention.

What is claimed is:

1. A solar cell, comprising:
a vertical multi-junction (VMJ) cell including a plurality of PN junction substrates and a plurality of electrode layers, wherein the PN junction substrates are spaced from each other, and each of the PN junction substrates includes a P+ type diffuse doping layer, a P type diffuse doping layer, an N type diffuse doping layer and an N+ type diffuse doping layer, wherein the P+ type diffuse doping layer has a P+ type end surface; the P type diffuse doping layer is connected to the P+ type diffuse doping layer and has a P type end surface; the N type diffuse doping layer is connected to the P type diffuse doping layer and has an N type end surface; and the N+ type diffuse doping layer is connected to the N type diffuse doping layer and has an N+ type end surface, and each of the electrode layers is disposed between and connected to two adjacent PN junction substrates and has an exposing surface; and
a passivation layer covering the P+ type end surfaces of the P+ type diffuse doping layers, the P type end surfaces of the P type diffuse doping layers, the N type end surfaces of the N type diffuse doping layers, the N+ type end surfaces of the N+ type diffuse doping layers and the exposing surfaces of the electrode layers.

2. The solar cell of claim 1, wherein each of the PN junction substrates includes a light receiving surface, and the light receiving surface includes the P+ type end surface of the P+ type diffuse doping layer, the P type end surface of the P type diffuse doping layer, the N type end surface of the N type diffuse doping layer and the N+ type end surface of the N+ type diffuse doping layer.

3. The solar cell of claim 2, wherein the light receiving surface is an uneven surface.

4. The solar cell of claim 2, wherein there is a height difference between the exposing surface of each of the electrode layers and the light receiving surface of each of the PN junction substrates.

5. The solar cell of claim 4, wherein a position of the exposing surface is lower than that of the light receiving surface.

6. The solar cell of claim 4, wherein each of the electrode layers includes a groove recessed from the exposing surface, and a depth of the groove is greater than the height difference.

7. The solar cell of claim 1, wherein each of the electrode layers includes a groove recessed from the exposing surface, and the grooves are filled with the passivation layer.

8. The solar cell of claim 1, wherein a doping concentration of the P+ type diffuse doping layer is between about 10¹⁹ atom/cm³ and about 10²¹ atom/cm³.

9. The solar cell of claim 1, wherein a thickness of the P+ type diffuse doping layer is between about 0.3 μm and about 3 μm.

10. The solar cell of claim 1, wherein a doping concentration of the P type diffuse doping layer is between about 10¹⁶ atom/cm³ and about 10²⁰ atom/cm³.

11. The solar cell of claim 1, wherein a thickness of the P type diffuse doping layer is between about 1 μm and about 50 μm.

12. The solar cell of claim 1, wherein a doping concentration of the N type diffuse doping layer is between about 10¹⁶ atom/cm³ and about 10²⁰ atom/cm³.

13. The solar cell of claim 1, wherein a thickness of the N type diffuse doping layer is between about 1 μm and about 50 μm.

14. The solar cell of claim 1, wherein a doping concentration of the N+ type diffuse doping layer is between about 10¹⁹ atom/cm³ and about 10²¹ atom/cm³.

15. The solar cell of claim 1, wherein a thickness of the N+ type diffuse doping layer is between about 0.3 μm and about 3 μm.

16. The solar cell of claim 1, wherein each of the PN junction substrates further comprises a P− type diffuse doping layer disposed between and connected to the P type diffuse doping layer and the N type diffuse doping layer.

17. The solar cell of claim 16, wherein the P− type diffuse doping layer has a P− type end surface, and the P− type end surface is covered with the passivation layer.

18. The solar cell of claim 16, wherein a doping concentration of the P− type diffuse doping layer is between about 10¹⁴ atom/cm³ and about 10¹⁸ atom/cm³.

19. The solar cell of claim 1, wherein each of the PN junction substrates further comprises an N− type diffuse doping layer disposed between and connected to the P type diffuse doping layer and the N type diffuse doping layer.

20. The solar cell of claim 19, wherein the N− type diffuse doping layer has an N− type end surface, and the N− type end surface is covered with the passivation layer.

21. The solar cell of claim 19, wherein a doping concentration of the N− type diffuse doping layer is between about 10¹⁴ atom/cm³ and about 10¹⁸ atom/cm³.

22. The solar cell of claim 1, wherein the PN junction substrates are made of one selected from the group consisting of Si, GaAs, Ge, InGaP, and their compositions.

23. The solar cell of claim 1, wherein the passivation layer is formed by an atomic layer deposition (ALD) process.

24. The solar cell of claim 1, wherein the passivation layer is penetrable to light.

25. The solar cell of claim 1, wherein the passivation layer is made of one selected from the group consisting of, HfO₂, La₂O₃, SiO₂, TiO₂, ZnO, ZrO₂, Al₂O₃, Ta₂O₅, In₂O₃, SnO₂, ITO, Fe₂O₃, Nb₂O₅, MgO, Er₂O₃, WN, Hf₃N₄, Zr₃N₄, AlN, and TiN.

26. The solar cell of claim 1, wherein the VMJ cell includes a first end surface, a second end surface opposite to the first end surface and at least two conducting electrodes separately disposed on the first and second end surfaces, and the conducting electrodes are covered with the passivation layer.

27. The solar cell of claim 1, wherein the VMJ cell includes a first end surface, a second end surface opposite to the first end surface and at least two conducting electrodes separately disposed on the first and second end surfaces, and the first end surface and the second end surface are covered with the passivation layer.

28. The solar cell of claim 1, further comprising an anti-reflective layer covering part of the passivation layer, wherein the anti-reflective layer is penetrable to light.

29. A method of manufacturing a solar cell, comprising:
providing a vertical multi-junction (VMJ) cell including a plurality of PN junction substrates and a plurality of electrode layers, wherein the PN junction substrates are spaced from each other, and each of the PN junction substrates includes a P+ type diffuse doping layer, a P type diffuse doping layer, an N type diffuse doping layer and an N+ type diffuse doping layer, wherein the P+ type diffuse doping layer has a P+ type end surface; the P type diffuse doping layer is connected to the P+ type diffuse doping layer and has a P type end surface; the N type diffuse doping layer is connected to the P type diffuse doping layer and has an N type end surface; and the N+ type diffuse doping layer is connected to the N type diffuse doping layer and has an N+ type end surface, and each of the electrode layers is disposed between and connected to two adjacent PN junction substrates and has an exposing surface; and
forming a passivation layer on the VMJ cell to cover the P+ type end surfaces of the P+ type diffuse doping layers, the P type end surfaces of the P type diffuse doping layers, the N type end surfaces of the N type diffuse doping layers, the N+ type end surfaces of the N+ type diffuse doping layers and the exposing surfaces of the electrode layers.

30. The method of claim 29, wherein the passivation layer is formed by an atomic layer deposition (ALD) process.

31. The method of claim 29, wherein the VMJ cell includes a first end surface, a second end surface opposite to the first end surface and at least two conducting electrodes separately disposed on the first and second end surfaces, and further comprising forming the passivation layer to cover the conducting electrodes.

32. The method of claim 29, wherein the VMJ cell includes a first end surface, a second end surface opposite to the first end surface and at least two conducting electrodes separately disposed on the first and second end surfaces, and further comprising forming the passivation layer to cover the first end surface and the second end surface.

33. The method of claim 29, wherein each of the electrode layers includes a groove recessed from the exposing surface, and further comprising forming the passivation layer to fill the grooves.

34. The method of claim 29, wherein each of the PN junction substrates further comprises a P− type diffuse doping layer disposed between and connected to the P type diffuse doping layer and the N type diffuse doping layer, and further comprising forming the passivation layer to cover a P− type end surface of the P− type diffuse doping layer.

35. The method of claim 29, wherein each of the PN junction substrates further comprises an N− type diffuse doping layer disposed between and connected to the P type diffuse doping layer and the N type diffuse doping layer, and further comprising forming the passivation layer to cover an N− type end surface of the N-type diffuse doping layer.

36. The method of claim 29, wherein the passivation layer is penetrable to light.

37. The method of claim 29, further comprising forming an anti-reflective layer to cover part of the passivation layer, wherein the anti-reflective layer is penetrable to light.
